(19) United States
(12) Patent Application Publication
(10) Pub. No.: US 2013/0049122 A1
(43) Pub. Date: Feb. 28, 2013

(54) SEMICONDUCTOR DEVICE AND METHOD OF MANUFACTURING THE SAME

(71) Applicants: Toshitaka MIYATA, Yokohama-shi (JP); Nobutoshi Aoki, Yokohama-shi (JP)

(72) Inventors: Toshitaka MIYATA, Yokohama-shi (JP); Nobutoshi Aoki, Yokohama-shi (JP)

(73) Assignee: Kabushiki Kaisha Toshiba, Tokyo (JP)

(21) Appl. No.: 13/534,665

(22) Filed: Jun. 27, 2012

(30) Foreign Application Priority Data
Aug. 25, 2011 (JP) 2011-183788

(51) Int. Cl. H01L 29/78; H01L 21/283

(52) U.S. Cl. 257/366; 438/593; 257/E29.264; 257/E21.19

(57) ABSTRACT

In one embodiment, a semiconductor device includes a substrate, and a gate insulator disposed on the substrate. The device further includes a gate electrode including a first electrode layer which is disposed on an upper surface of the gate insulator and has a first work function, and a second electrode layer which is continuously disposed on the upper surface of the gate insulator and an upper surface of the first electrode layer and has a second work function that is different from the first work function, and sidewall insulators disposed on side surfaces of the gate electrode. A height of the upper surface of the first electrode layer is lower than a height of upper surfaces of the sidewall insulators.

### CROSS REFERENCE TO RELATED APPLICATION

This application is based upon and claims the benefit of priority from the prior Japanese Patent Application No. 2011-183788, filed on Aug. 25, 2011, the entire contents of which are incorporated herein by reference.

### FIELD

Embodiments described herein relate to a semiconductor device and a method of manufacturing the same.

### BACKGROUND

A gate electrode of a dual work function FET (DWF-FET) includes a first electrode layer having a first work function, and a second electrode layer having a second work function that is different from the first work function. The first and second electrode layers are disposed adjacent to each other in a gate length direction.

For example, the DWF-FET is formed by forming the first electrode layer and a dummy electrode on a substrate via a gate insulator, surrounding the side surfaces of the first electrode layer and the dummy electrode with an inter layer dielectric, removing the dummy electrode to form a hole in the inter layer dielectric, and embedding the second electrode layer in the hole.

According to the DWF-FET, the substantial gate length is shortened from the width of the gate electrode to the width of the first or second electrode layer, so that a drain current of the FET can be increased. Furthermore, although a maximum transmission frequency of the FET is inversely proportional to the ½ power of the gate resistance, the gate resistance of the DWF-FET can be reduced compared to a general FET. Therefore, according to the DWF-FET, high frequency characteristics of the FET can be improved.

However, when the hole is minute in the DWF-FET, it is difficult to embed the second electrode layer in the hole and therefore it is difficult to form the gate electrode.

### BRIEF DESCRIPTION OF THE DRAWINGS

FIG. 1 is a cross-sectional view showing a structure of a semiconductor device according to a first embodiment;

FIGS. 2A to 8B are cross-sectional views showing a method of manufacturing the semiconductor device according to the first embodiment; and

FIG. 9 is a cross-sectional view showing a structure of a semiconductor device according to a second embodiment.

### DETAILED DESCRIPTION

Embodiments will now be explained with reference to the accompanying drawings.

An embodiment described herein is a semiconductor device including a substrate, and a gate insulator disposed on the substrate. The device further includes a gate electrode including a first electrode layer which is disposed on an upper surface of the gate insulator and has a first work function, and a second electrode layer which is continuously disposed on the upper surface of the gate insulator and an upper surface of the first electrode layer and has a second work function that is different from the first work function, and sidewall insulators disposed on side surfaces of the gate electrode. A height of the upper surface of the first electrode layer is lower than a height of upper surfaces of the sidewall insulators.

### First Embodiment

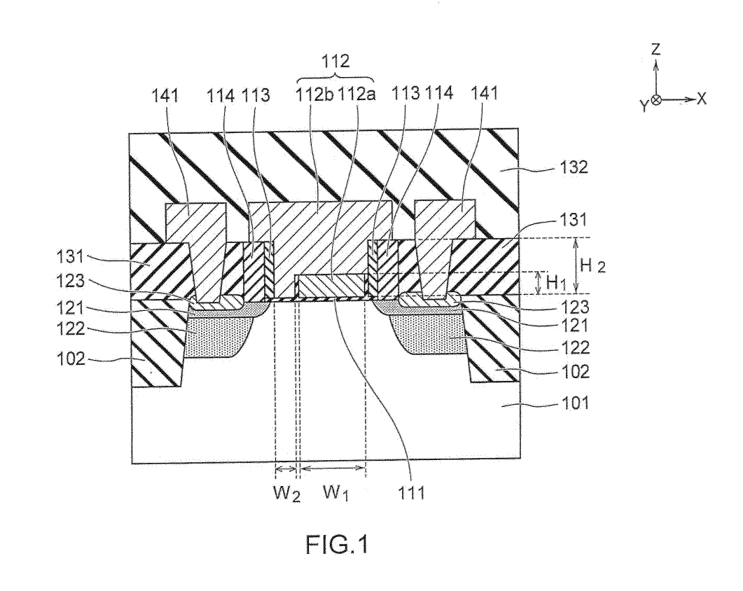

FIG. 1 is a cross-sectional view showing a structure of a semiconductor device according to a first embodiment.

The semiconductor device of FIG. 1 includes a semiconductor substrate 101, a gate insulator 111, a gate electrode 112, first sidewall insulators 113, second sidewall insulators 114, first impurity diffusion layers 121, and second impurity diffusion layers 122 as components of a DWF-FET.

The semiconductor substrate 101 is, for example, a silicon substrate. FIG. 1 shows X and Y directions which are parallel to a principal surface of the semiconductor substrate 101 and orthogonal to each other, and a Z direction which is orthogonal to the principal surface of the semiconductor substrate 101. The X and Y directions correspond to a gate length direction and a channel width direction of the DWF-FET, respectively.

Isolation insulators 102 for electrically isolating DWF-FETs from each other are formed in the semiconductor substrate 101. The isolation insulators 102 are, for example, silicon oxide films formed by the shallow trench isolation (STI) method.

The first impurity diffusion layers 121 are formed in the semiconductor substrate 101 to sandwich the gate electrode 112. The second impurity diffusion layers 122 are formed under the first impurity diffusion layers 121 in the semiconductor substrate 101 to sandwich the gate electrode 112. The second impurity diffusion layer 122 on a left side of the drawing corresponds to a source layer, and the second impurity diffusion layer 122 on a right side of the drawing corresponds to a drain layer. The first impurity diffusion layers 121 correspond to extension layers.

Silicide layers 123 are formed on upper surfaces of the first impurity diffusion layers 121. Examples of the silicide layers 123 include nickel silicide (NiSi) layers and cobalt silicide (CoSi) layers.

The gate insulator 111 is formed on the semiconductor substrate 101. The gate insulator 111 is, for example, a silicon oxide film formed by thermal oxidation.

The gate electrode 112 is formed on the semiconductor substrate 101 via the gate insulator 111. The gate electrode 112 includes a first electrode layer 112a having a first work function, and a second electrode layer 112b having a second work function that is different from the first work function. For example, the first electrode layer 112a is a polysilicon layer, and the second electrode layer 112b is a metal layer formed of metal material having a larger work function than that of polysilicon. An example of the metal layer includes a tungsten (W) layer. The first and second electrode layers 112a and 112b may be a semiconductor layer other than the polysilicon layer and a metal layer formed of metal material having a larger work function than that of the semiconductor layer, respectively.

The first electrode layer 112a is formed on an upper surface of the gate insulator 111. The second electrode layer 112b is continuously formed on the upper surface of the gate insulator 111 and an upper surface of the first electrode layer 112a. The first and second electrode layers 112a and 112b are located on a drain layer side and a source layer side at a lower surface of the gate electrode 112, respectively. In this embodiment, the gate insulator 111 is also formed on a side surface of the first electrode layer 112a. The reasons why such structure is provided will be explained later.

The first sidewall insulators 113 are formed on side surfaces of the gate electrode 112. The second sidewall insulators 114 are formed on the side surfaces of the gate electrode 112 via the first sidewall insulators 113. Examples of the first and second sidewall insulators 113 and 114 are silicon oxide films. As shown in FIG. 1, the second electrode layer 112b extends to upper surfaces of the first and second sidewall insulators 113 and 114.

The semiconductor device of FIG. 1 further includes a first inter layer dielectric 131 formed on the semiconductor substrate 101 to surround the DWF-FET, and contact plugs 141 formed on the silicide layers 123 in the first inter layer dielectric 131. In this embodiment, the contact plugs 141 are formed of the same electrode material as the second electrode layer 112b. The semiconductor device of FIG. 1 further includes a second inter layer dielectric 132 on the first inter layer dielectric 131 to cover the DWF-FET and the contact plugs 141.

(1) Details of Structure of Gate Electrode 112

The structure of the gate electrode 112 will be explained in detail with reference to FIG. 1.

Symbols W₁ and W₂ shown in FIG. 1 indicate a width of the first electrode layer 112a in the X direction and a width of the second electrode layer 112b in the X direction at the lower surface of the gate electrode 112, respectively. A symbol H₁ indicates a height from a lower surface of the first electrode layer 112a to the upper surface of the first electrode layer 112a. A symbol H₂ indicates a height from lower surfaces of the first sidewall insulators 121 to the upper surfaces of the first sidewall insulators 121. The height H₁ corresponds to a thickness of the first electrode layer 112a.

The values of the heights H₁ and H₂ are sufficiently larger than a thickness of the gate insulator 111. Therefore, the height H₁ is approximately equal to a height from an upper surface of the semiconductor substrate 101 to the upper surface of the first electrode layer 112a, and the height H₂ is approximately equal to a height from the upper surface of the semiconductor substrate 101 to the upper surface of the first sidewall insulator 121. Accordingly, the heights H₁ and H₂ correspond to a height to the upper surface of the first electrode layer 112a and a height to the upper surfaces of the first sidewall insulators 121 from the same reference point, respectively.

The widths W₁ and W₂ will be explained below in detail.

In this embodiment, the gate electrode 112 includes the first electrode layer 112a and the second electrode layer 112b. The first and second electrode layers 112a and 112b are disposed adjacent to each other in the X direction. In addition, the first electrode layer 112a is located on the drain layer side, and the second electrode layer 112b is located on the source layer side. Therefore, the substantial gate length in this embodiment is shortened from the width of the gate electrode 112 (W₁+W₂) to the width of the second electrode layer 112b (W₂). Accordingly, the drain current of the FET can be increased according to this embodiment.

In this embodiment, the substantial gate length can be shortened by reducing the width W₂. Therefore, the width W₂ is set to be shorter than the width W₁ in this embodiment (W₂<W₁). At this time, the drain current can be increased compared to when the width W₂ is set to be larger than the width W₁. In this embodiment, for example, the width W₁ is set to be 120 to 140 nm and the width W₂ is set to be 20 to 40 nm.

The heights H₁ and H₂ will be explained below in detail.

In this embodiment, the second electrode layer 112b is embedded in the hole between the first electrode layer 112a and the first sidewall insulator 121 as described later. If this hole is minute, it is difficult to embed the second electrode layer 112b in the hole. Since the width of this hole is equal to the width W₂, it becomes more difficult to embed the second electrode layer 112b when the width W₂ is reduced for shortening the substantial gate length.

Therefore, the first electrode layer 112a in this embodiment is thinned before the second electrode layer 112b is embedded in the hole, so that the height H₁ of the upper surface of the first electrode layer 112b becomes lower than the height H₂ of the upper surfaces of the first sidewall insulators 121 (H₁<H₂). Consequently, a width of an opening through which the second electrode layer 112b is embedded is increased from the width W₂ to the width W₁+W₂, so that the second electrode layer 112b can be easily embedded in the hole.

The second electrode layer 112b is embedded easily as the height H₁ is reduced. In this embodiment, the height H₁ is equal to or lower than half of the height H₂ (H₁≦H₂/2). As compared to when the height H₁ is higher than half of the height H₂, the second electrode layer 112b can be easily embedded. In this embodiment, for example, the height H₂ is set to be 70 to 90 nm, and the height H₁ is set to be 20 to 40 nm.

Since the height H₁ is set to be shorter than the height H₂ in this embodiment, the second electrode layer 112b is easily embedded even when the width W₂ is set to be sufficiently shorter than the width W₁. In this embodiment, the width W₂ may be equal to or shorter than half of the width W₁ as described in the above numerical example (W₂≦W₁/2).

The gate resistance of the gate electrode 112 will be explained below in detail.

In this embodiment, the first electrode layer 112a is a polysilicon layer, and the second electrode layer 112b is a metal layer. In General, the electrical resistivity of metal material is lower than that of polysilicon. Therefore, the gate resistance in this embodiment can be reduced compared to a general FET in which the gate electrode 112 is formed of only polysilicon. Since the height H₁ is set to be shorter than the height H₂ in this embodiment, the ratio of the second electrode layer 112b to the gate electrode 112 is reduced, so that the gate resistance can be further reduced.

In this embodiment, since the height H₁ is set to be lower than the height H₂, the gate resistance can be reduced and the high frequency characteristic of the FET can be improved.

As described above, this embodiment can provide the DWF-FET including the gate electrode 112 which includes plural electrode layers 112a and 112b having different work functions, has a low gate resistance, and is easily manufactured.

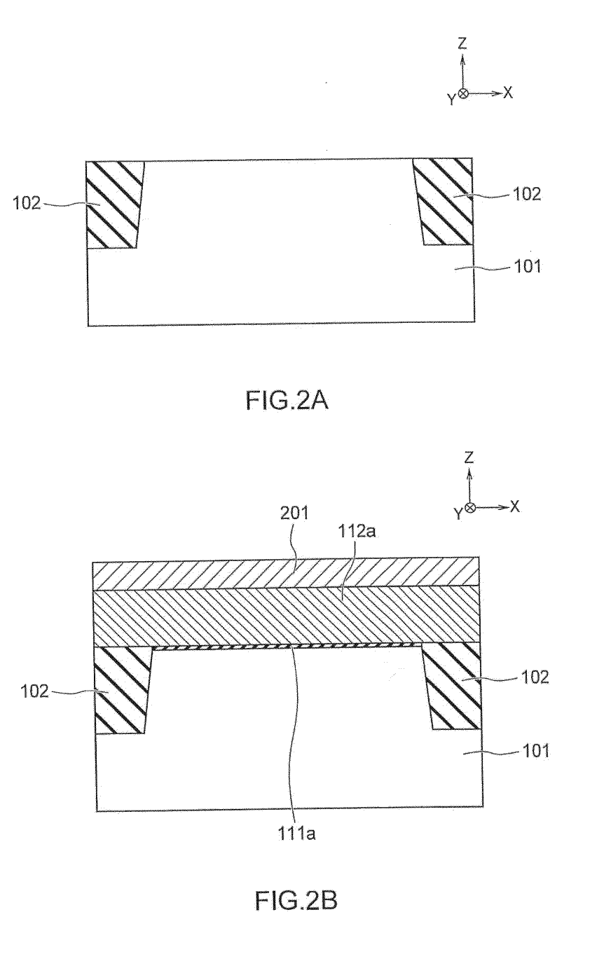

(2) Method of Manufacturing Semiconductor Device A method of manufacturing the semiconductor device of the first embodiment will be explained with reference to FIGS. 2A to 8B.

FIGS. 2A to 8B are cross-sectional views showing the method of manufacturing the semiconductor device according to the first embodiment.

First, the semiconductor substrate 101 is prepared (FIG. 2A). Next, the isolation insulators 102 are formed in the semiconductor substrate 101 (FIG. 2A). For example, the isolation insulators 102 are formed by forming isolation trenches in the semiconductor substrate 101, embedding an isolator in the isolation trenches, and planarizing a surface of the isolator. Impurities for adjusting a threshold voltage of the DWF-FET are then introduced in device regions of the semiconductor substrate 101 by, for example, ion implantation.

As shown in FIG. 2B, a first insulator 111a for forming the gate insulator 111 is formed on the device regions of the semiconductor substrate 101 by, for example, thermal oxidation. The first electrode layer 112a for forming the gate electrode 112 is then deposited on the entire surface of the semiconductor substrate 101. The thickness of the first electrode layer 112a is, for example, 100 nm. Next, impurities are introduced in the first electrode layer 112a by, for example, ion implantation. A hard mask layer 201 for protecting the first electrode layer 112a is then deposited on the entire surface of the semiconductor substrate 101 by, for example, chemical vapor deposition (CVD). A thickness of the hard mask layer 201 is, for example, 50 nm.

In this embodiment, a metal layer such as a tungsten (W) layer is used as the hard mask layer 201. Since first and second dummy electrodes 211 and 212 described later are silicon nitride films, the hard mask layer 201 is required to be made of material having an etching selection ratio to the silicon nitride films.

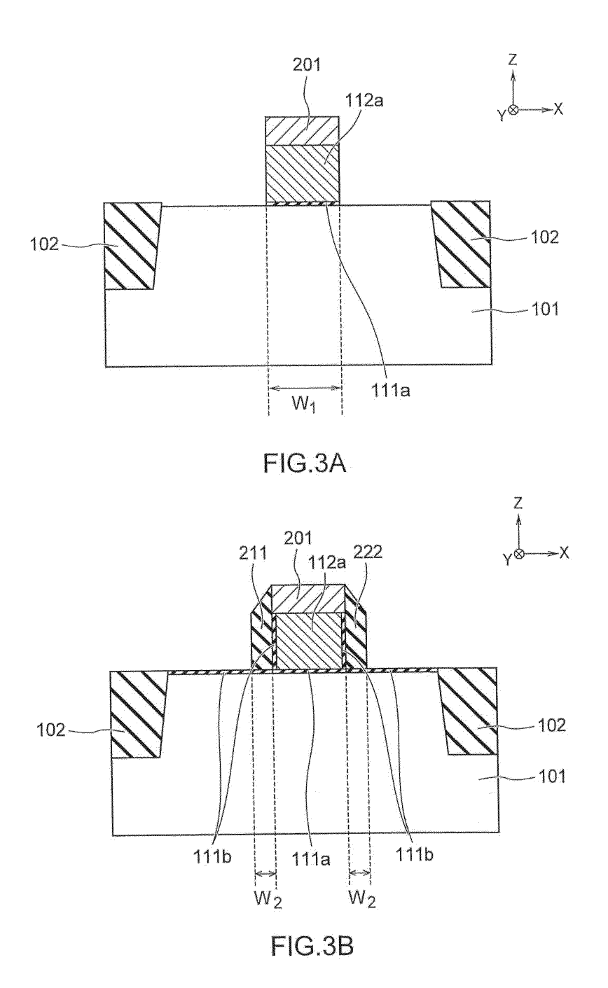

Next, the hard mask layer 201 is etched by reactive ion etching (RIE) or the like using a resist film as a mask (FIG. 3A). At this time, a width of the hard mask layer 201 in the X direction is set to be W₁. The first electrode layer 112a is then etched by RIE or the like using the hard mask layer 201 as a mask (FIG. 3A).

While the first electrode layer 112a is etched, a portion of the first insulator 111a where the first electrode layer 112a remains is protected, but the other portion of the first insulator 111a where the first electrode layer 112a is removed is damaged by RIE or is removed. Therefore, in this embodiment, a process for restoring the damaged first insulator 111a or forming a similar insulator as the removed first insulator 111a is carried out to form an insulator having a predetermined thickness. This process is carried out by, for example, thermal oxidation.

This insulator is used as a second insulator 111b for forming the gate insulator 111. As shown in FIG. 3B, the second insulator 111b is formed on the device regions of the semiconductor substrate 101 and side surfaces of the first electrode layer 112a.

As shown in FIG. 3B, the first and second dummy electrodes 211 and 212 are then formed on the side surfaces of the first electrode layer 112a and the hard mask layer 201 on the second insulator 111b. At this time, a thickness of each dummy electrode 211, 212 is set to be W₂. Since the dummy electrodes 211 and 212 are not used as real electrodes, the dummy electrodes 211 and 212 may be formed of material other than electrode material. For example, the dummy electrodes 211 and 212 may be formed of insulating material. The dummy electrodes 211 and 212 are, for example, silicon nitride films. The dummy electrodes 211 and 212 are formed by, for example, depositing a silicon nitride film having a thickness of 30 nm on the entire surface of the semiconductor substrate 101 by CVD, and etching the silicon nitride film by RIE.

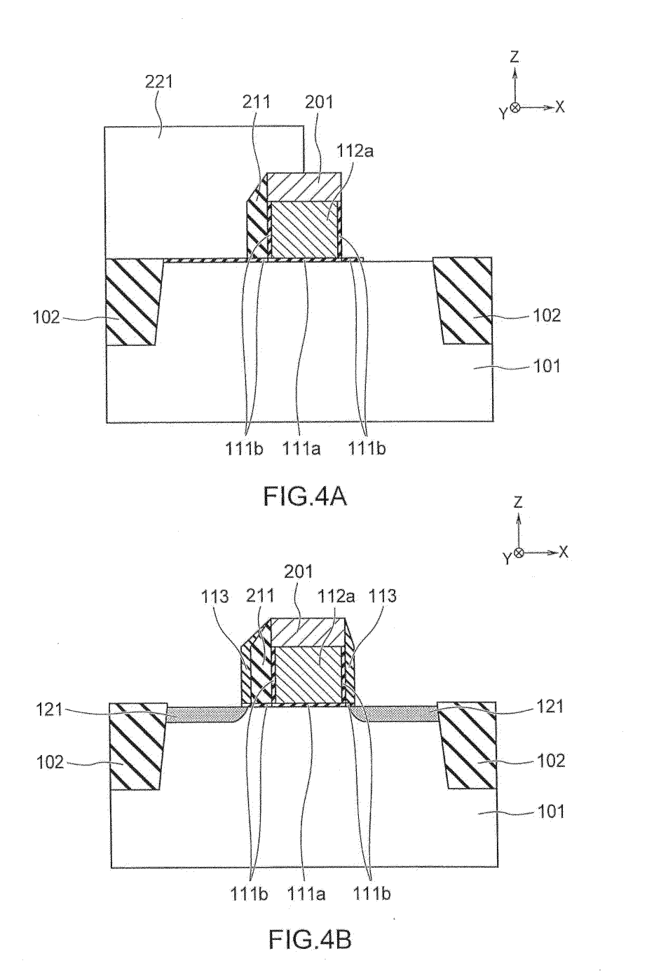

As shown in FIG. 4A, the first dummy electrode 211 on the source layer side is covered with a resist film 221. Next, the second dummy electrode 212 on the drain layer side is removed by wet etching using the resist film 221 as a mask. The resist film 221 is then removed.

As shown in FIG. 4B, the first sidewall insulators 113 are formed on the side surfaces of the first electrode layer 112a, the hard mask layer 201, and the first dummy electrode 211 on the second insulator 111b. For example, the first sidewall insulators 113 are formed by depositing a silicon oxidation film having a thickness of 5 nm on the entire surface of the semiconductor substrate 101 by CVD, and etching the silicon oxidation film by RIE.

As shown in FIG. 4B, ions are then implanted in the semiconductor substrate 101 to form the first impurity diffusion layers 121. An example of the impurities used in this process to form an N-type DWF-FET is arsenic (As). The ions are implanted under conditions that an acceleration voltage is 1.0 keV and a dose amount is 1.0×10¹⁵ cm⁻².

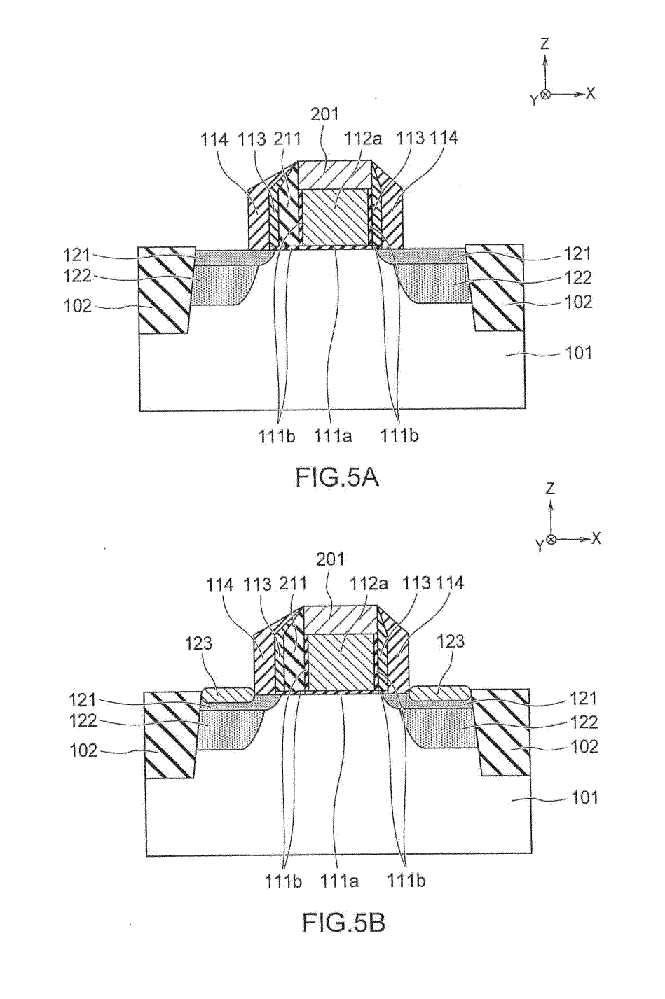

As shown in FIG. 5A, the second sidewall insulators 114 are formed on the side surfaces of the first electrode layer 112a, the hard mask layer 201, and the first dummy electrode 211 via the first sidewall insulators 113 on the semiconductor substrate 101. The second sidewall insulators 114 are formed by depositing a silicon oxidation film having the thickness of 30 nm on the entire surface of the semiconductor substrate 101 by CVD and etching the silicon oxidation film by RIE.

As shown in FIG. 5A, ions are then implanted in the semiconductor substrate 101 to form the second impurity diffusion layers 122. An example of the impurities used in this process to form the N-type DWF-FET is arsenic (As). The ions are implanted under the conditions that the acceleration voltage is 20 keV and the dose amount is 3.0×10¹⁵ cm⁻².

Next, annealing treatment is performed for activating the impurities introduced by ion implantation. For example, spike annealing may be performed at 1050° C. as the annealing treatment. Silicide layers 123 are then formed on the first impurity diffusion layers 121 as shown in FIG. 5B.

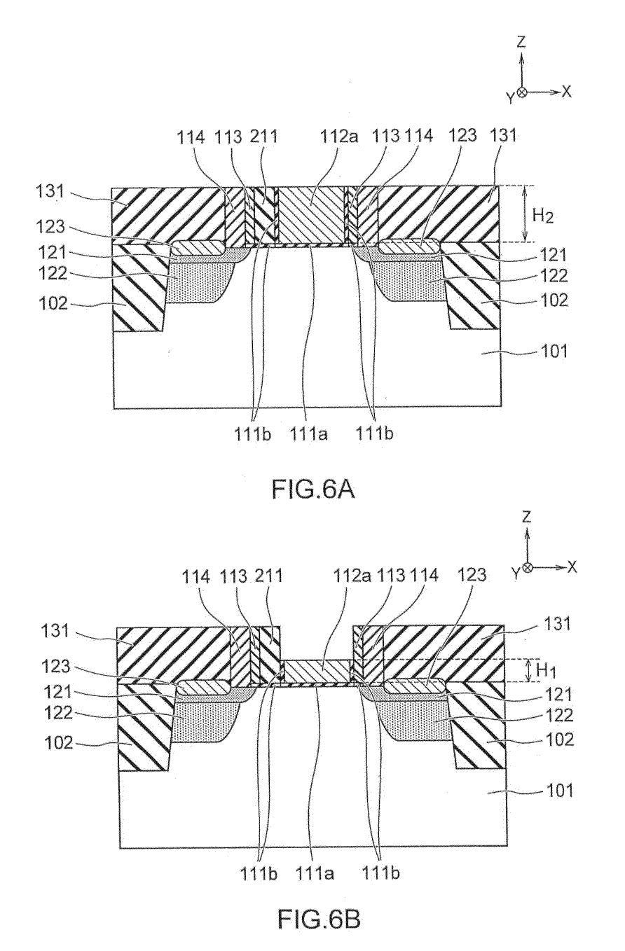

Next, the first inter layer dielectric 131 is deposited on the entire surface of the semiconductor substrate 101 by, for example, CVD (FIG. 6A). The first inter layer dielectric 131 is formed to cover the first electrode layer 112a, the hard mask layer 201, the first dummy electrode 211 and the like.

Next, the surface of the first inter layer dielectric 131 is planarized by chemical mechanical polishing (CMP) to expose the first electrode layer 112a, the first dummy electrode 211, and the first and second sidewall insulators 113 and 114 (FIG. 6A). This planarization process is carried out until the height from the lower surfaces to the upper surfaces of those components becomes equal to H₂.

Next, the height of the upper surface of the first electrode layer 112a is adjusted by, for example, wet etching (FIG. 6B). Consequently, the first electrode layer 112a is thinned, and the upper surface of the first electrode layer 112a is recessed compared to the upper surface of the first inter layer dielectric 131 and the like. The wet etching is carried out until the thickness of the first electrode layer 112a becomes equal to H₁. In this embodiment, H₁ is 30 nm for example.

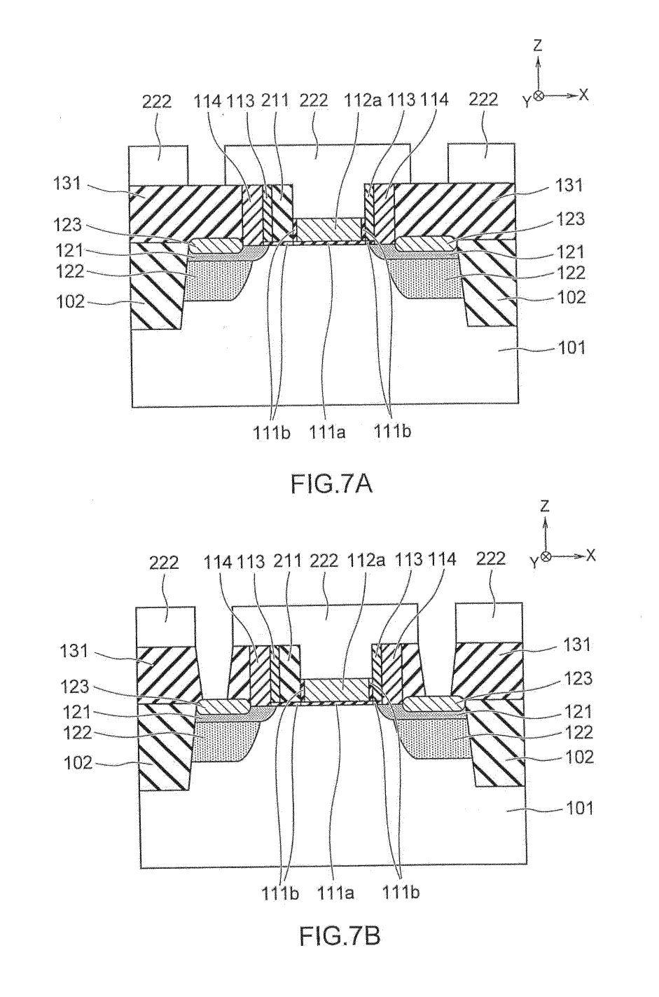

As shown in FIG. 7A, a resist film 222 for contact processing is then formed on the first inter layer dielectric 131. As shown in FIG. 7B, contact holes are formed on the silicide layers 123 in the first inter layer dielectric 131 by RIE using the resist film 222 as a mask. The resist film 222 is then removed.

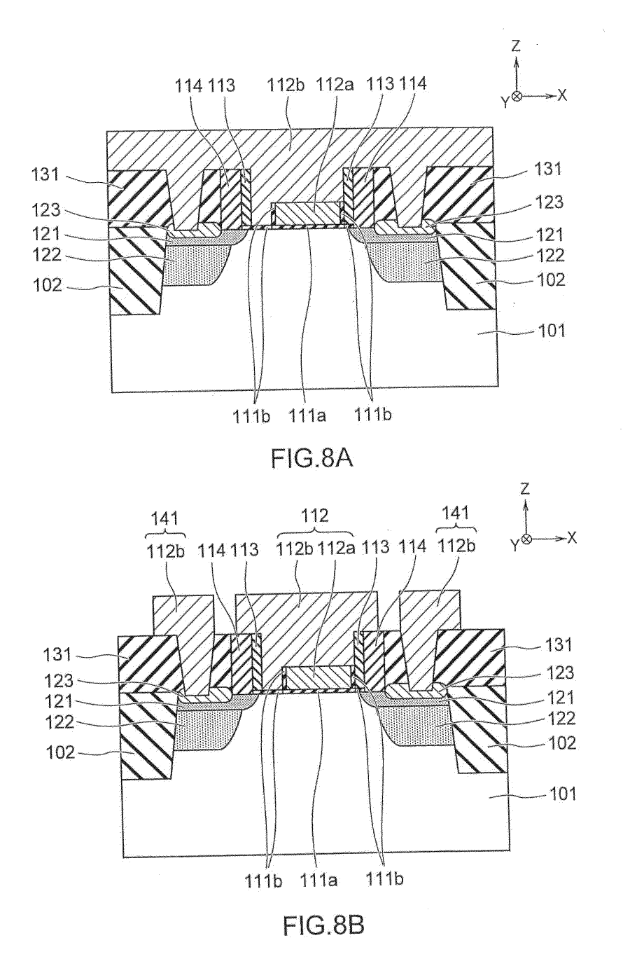

The first dummy electrode 211 is then removed by, for example, wet etching to form a hole in the first inter layer dielectric 131 (FIG. 8A). The second insulator 111b is exposed in this hole.

As shown in FIG. 8A, the second electrode layer 112b for forming the gate electrode 112 is then formed on the entire surface of the semiconductor substrate 101 by, for example, CVD. Consequently, the second electrode layer 112b is embedded in the hole and the contact holes. The second electrode layer 112b is continuously formed on the upper surface of the second insulator 111b in the hole and the upper surface of the first electrode layer 112a.

As shown in FIG. 8B, the second electrode layer 112b is etched by RIE using the resist film as a mask. In this way, an electrode layer portion of the gate electrode 112 and the contact plugs 141 are simultaneously provided from the second electrode layer 112b by damascene process.

Subsequently, the second inter layer dielectric 132, and other interconnect layers, via plugs, inter layer dielectrics and the like are formed by conventional methods in this embodiment. Consequently, the semiconductor device shown in FIG. 1 is manufactured.

According to this embodiment, the second electrode layer 112b can be easily embedded in the hole by thinning the first electrode layer 112a. Consequently, the second electrode layer 112b can be easily embedded in the hole so that any space is not left in the hole.

In addition, due to thinning the first electrode layer 112a, the ratio of the second electrode layer 112b to the gate electrode 112 can be reduced and therefore the gate resistance can be reduced according to this embodiment.

Since the first dummy electrode 211 is removed by wet etching in this embodiment, the damage to the gate insulator 111 (second insulator 111b) can be reduced.

(3) Effects of First Embodiment

The effects of the first embodiment will be explained below.

As described above, the height H₁ of the upper surface of the first electrode layer 112b is set to be lower than the height H₂ of the upper surface of the first sidewall insulator 121 in this embodiment (H₁<H₂). Accordingly, the ratio of the second electrode layer 112b to the gate electrode 112 can be reduced and therefore the gate resistance can be reduced according to this embodiment. In addition, according to this embodiment, the second electrode layer 112b can be easily embedded by damascene process and therefore the gate electrode 112 can be easily manufactured. Since the second electrode layer 112b is easily embedded according to this embodiment, the substantial gate length can be effectively reduced by setting the width W₂ of the second electrode layer 112b be sufficiently shorter than the width W₁ of the first electrode layer 112a.

As described above, this embodiment can provide the DWF-FET including the gate electrode 112 which includes plural electrode layers 112a and 112b having different work functions, has a low gate resistance, and is easily manufactured.

### Second Embodiment

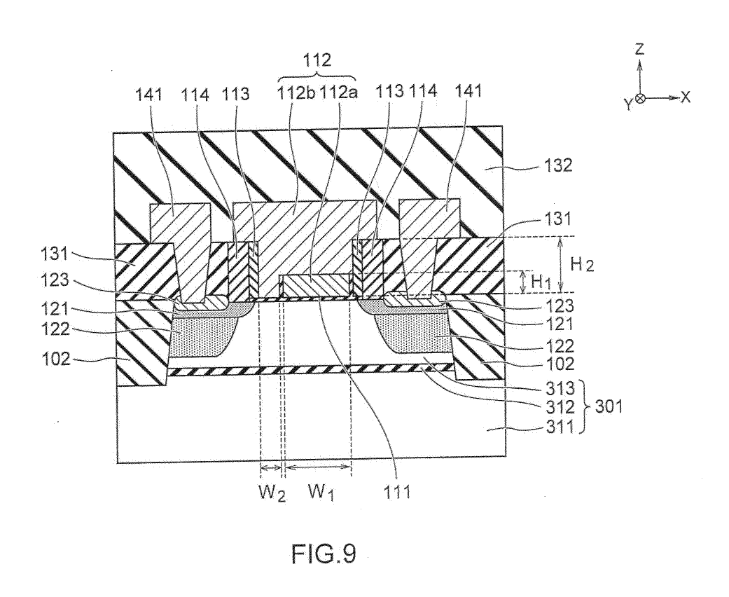

FIG. 9 is a cross-sectional view showing a structure of a semiconductor device according to a second embodiment.

In the semiconductor device of FIG. 9, a semiconductor on insulator (SOI) substrate 301 is provided instead of the semiconductor substrate 101. The SOI substrate 301 includes a semiconductor substrate 311, a buried insulator 312 on the semiconductor substrate 311, and a semiconductor layer 313 on the buried insulator 312. For example, the semiconductor substrate 311, the buried insulator 312, and the semiconductor layer 313 are a silicon substrate, a silicon oxidation film, and a silicon layer, respectively. The semiconductor layer 313 may be a silicon germanium layer or a germanium layer.

In FIG. 9, the isolation insulators 102 penetrate the buried insulator 312, and bottom surfaces of the isolation insulators 102 are positioned to be lower than the upper surface of the semiconductor substrate 301. The adjacent DWF-FETs in the X direction are separated by the isolation insulators 102 and the buried insulator 312. The first and second impurity diffusion layers 121 and 122 are formed in the semiconductor layer 313.

Since the adjacent DWF-FETs in the X direction are separated by the isolation insulators 102 and the buried insulator 312 in this embodiment, punch-through can be suppressed effectively compared to when the semiconductor substrate 101 is used as the first embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a substrate;
a gate insulator disposed on the substrate;
a gate electrode including a first electrode layer which is disposed on an upper surface of the gate insulator and has a first work function, and a second electrode layer which is continuously disposed on the upper surface of the gate insulator and an upper surface of the first electrode layer and has a second work function that is different from the first work function; and
sidewall insulators disposed on side surfaces of the gate electrode,
wherein a height of the upper surface of the first electrode layer is lower than a height of upper surfaces of the sidewall insulators.

2. The device of claim 1, wherein a width of the second electrode layer in a gate length direction is shorter than a width of the first electrode layer in the gate length direction at a lower surface of the gate electrode.

3. The device of claim 1, wherein a height from a lower surface of the first electrode layer to the upper surface of the first electrode layer is equal to or lower than half of a height from lower surfaces of the sidewall insulators to the upper surfaces of the sidewall insulators.

4. The device of claim 2, wherein the width of the second electrode layer in the gate length direction is equal to or shorter than half of the width of the first electrode layer in the gate length direction at the lower surface of the gate electrode.

5. The device of claim 1, wherein the second work function is larger than the first work function.

6. The device of claim 1, wherein the first electrode layer is a semiconductor layer, and the second electrode layer is a metal layer.

7. The device of claim 1, wherein the second electrode layer is disposed on the upper surface of the gate insulator, the upper surface of the first electrode layer, and the upper surfaces of the sidewall insulators.

8. The device of claim 1, further comprising an insulator disposed between a side surface of the first electrode layer and a side surface of the second electrode layer.

9. The device of claim 1, further comprising source and drain layers disposed in the substrate to sandwich the gate electrode,
wherein the first and second electrode layers are located on a drain layer side and on a source layer side at the lower surface of the gate electrode, respectively.

10. The device of claim 1, further comprising a contact plug disposed on the substrate and formed of the same material as the second electrode layer.

11. A method of manufacturing a semiconductor device, the method comprising:
forming a first electrode layer of a gate electrode on a substrate via a gate insulator;
forming a dummy electrode on a side surface of the first electrode layer;
forming sidewall insulators on side surfaces of the first electrode layer and the dummy electrode;
forming an inter layer dielectric on the substrate to cover the first electrode layer and the dummy electrode;
planarizing a surface of the inter layer dielectric to expose the first electrode layer and the dummy electrode;
thinning the first electrode layer to recess an upper surface of the first electrode layer compared to upper surfaces of the sidewall insulators;
removing the dummy electrode to form a hole in the inter layer insulator; and
forming a second electrode layer of the gate electrode continuously on a bottom surface of the hole and the upper surface of the first electrode layer.

12. The method of claim 11, wherein
the gate insulator comprises first and second insulators,
the first electrode layer is formed on the substrate via the first insulator, and
the dummy electrode is formed on the substrate via the second insulator.

13. The method of claim 12, wherein
the first insulator is formed on a surface of the substrate, and
the second insulator is formed on the surface of the substrate and a side surface of the first electrode layer.

14. The method of claim 12, wherein the second electrode layer is formed on the second insulator exposed in the hole.

15. The method of claim 11, wherein the dummy electrode is an insulator.

16. The method of claim 11, wherein the first electrode is formed by etching by using a hard mask layer formed of metal material as a mask.

17. The method of claim 11, wherein
the first electrode layer has a first work function, and
the second electrode layer has a second work function that is different from the first work function.

18. The method of claim 11, wherein the first electrode layer is a semiconductor layer, and the second electrode layer is a metal layer.

19. The method of claim 11, wherein the second electrode layer is formed on an upper surface of the gate insulator, the upper surface of the first electrode layer, and the upper surfaces of the sidewall insulators.

20. The method of claim 11, wherein a contact plug is simultaneously formed on the substrate with the second electrode layer.
